(19) United States
(12) Patent Application Publication
(10) Pub. No.: US 2025/0101582 A1
(43) Pub. Date: Mar. 27, 2025

(54) APPARATUS FOR TREATING SUBSTRATE

(71) Applicant: Samsung Electronics Co., Ltd., Suwon-si (KR)

(72) Inventor: Seung Jin YOU, Suwon-si (KR)

(21) Appl. No.: 18/779,226

(22) Filed: Jul. 22, 2024

(30) Foreign Application Priority Data
Sep. 27, 2023 (KR) 10-2023-0130757
Feb. 20, 2024 (KR) 10-2024-0024331

(51) Int. Cl. C23C 16/44

(52) U.S. Cl. CPC C23C 16/4409

(57) ABSTRACT

An apparatus for treating a substrate is provided. An apparatus for treating a substrate comprises a first body, a second body forming a chamber space therein in contact with the first body, a first gas supply line installed in the first body and a first connection portion, and a second gas supply line installed in the second body and a second connection portion, the second connection portion configured to contact the first connection portion, wherein the first connection portion includes a sealing groove, into which a gasket is inserted, on a surface that is in contact with the second connection portion, an inner wall separating a first flow path of the first gas supply line from the sealing groove, and a trench installed on the inner wall and fluidly connecting the first flow path to the sealing groove.

### CROSS-REFERENCE TO RELATED APPLICATION

This application claims priority to Korean Patent Application No. 10-2023-0130757 filed on Sep. 27, 2023 and No. 10-2024-0024331 filed on Feb. 20, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to an apparatus for treating a substrate.

### Description of the Related Art

Various processes such as deposition, photography, etching, cleaning, etc. are performed to fabricate a semiconductor device.

In performing a deposition process, a gas line for supplying a process gas to a process chamber is connected to the process chamber, and a sealing member such as O-ring is used to seal a space between the gas line and the outside.

However, as the outside air or the process gas flowing into a fastening surface between an O-ring and an O-ring groove may not be discharged smoothly, and contamination may occur. This may cause contamination to the entire gas line, and may lead to a defect in a substrate treating process.

Therefore, it is required that a contaminant flowing into the fastening surface should be discharged smoothly.

### BRIEF SUMMARY

Aspects of the present disclosure provide an apparatus for treating a substrate in which durability is improved.

The objects of the present disclosure are not limited to those mentioned above and additional objects of the present disclosure, which are not mentioned herein, will be clearly understood by those skilled in the art from the following description of the present disclosure.

According to an aspect of the present disclosure, there is provided an apparatus for treating a substrate comprising a first body, a second body forming a chamber space therein in contact with the first body, a first connection portion disposed between the first body and the second body, a second connection portion disposed between the first body and the second body, a first gas supply line installed in the first body and the first connection portion, and a second gas supply line installed in the second body and the second connection portion, the second connection portion configured to contact the first connection portion, wherein the first connection portion includes a sealing groove, into which a gasket is inserted, on a surface that is in contact with the second connection portion, an inner wall separating a first flow path of the first gas supply line from the sealing groove, and a trench installed on the inner wall and fluidly connecting the first flow path to the sealing groove.

According to the aforementioned and other embodiments of the present disclosure, an apparatus for treating a substrate, the apparatus comprising a first body, a second body forming a chamber space therein in contact with the first body, and a gasket surrounding the chamber space and sealing the chamber space from an outside, wherein the first body includes a sealing groove, into which the gasket is inserted, on a surface that is in contact with the second body, an inner wall separating the sealing groove from the chamber space, and a trench installed on the inner wall and fluidly connecting the chamber space to the sealing groove.

According to the aforementioned and other embodiments of the present disclosure, an apparatus for treating a substrate, the apparatus comprising a first body, a second body forming a chamber space therein in contact with the first body, a first gas supply line installed in the first body and in a first connection portion, and a second gas supply line installed in the second body and in a second connection portion configured to contact the first connection portion, wherein the first connection portion includes a sealing groove, into which a gasket is inserted, on a surface that is in contact with the second connection portion, an inner wall separating a first flow path of the first gas supply line from the sealing groove, and one or more trenches installed on the inner wall and fluidly connecting the first flow path to the sealing groove, a height of the inner wall is greater than a depth of the trench, and the depth of the trench is greater than half of a height of the gasket.

### BRIEF DESCRIPTION OF THE DRAWINGS

FIGS. 1 and 2 are schematic cross-sectional views illustrating an apparatus for treating a substrate according to some embodiments.

FIG. 3 is a perspective view illustrating a region X shown in FIG. 2.

FIG. 4 is a perspective view illustrating a region X and a region X′, which are shown in FIG. 2.

FIG. 5 is a cross-sectional view taken along line A-A′ of FIG. 4.

FIG. 6 is a cross-sectional view illustrating a region S shown in FIG. 5.

FIGS. 7 and 8 are cross-sectional views illustrating some elements of an apparatus for treating a substrate according to some embodiments.

FIG. 9 is a perspective view illustrating some elements of an apparatus for treating a substrate according to some embodiments.

FIG. 10 is a cross-sectional view taken along line B-B′ of FIG. 9.

FIGS. 11 to 13 are perspective views illustrating some elements of an apparatus for treating a substrate according to some embodiments.

FIG. 14 is a perspective view illustrating some elements of an apparatus for treating a substrate according to some embodiments.

FIG. 15 is a cross-sectional view illustrating a region Y shown in FIG. 2.

FIGS. 16 to 18 are cross-sectional views illustrating a region Z shown in FIG. 2.

### DETAILED DESCRIPTION OF THE DISCLOSURE

Hereinafter, the embodiments of the present disclosure will be described in detail with reference to the accompanying drawings. The same reference numerals will be used for the same elements on the drawings and a repeated description of the corresponding elements will be omitted.

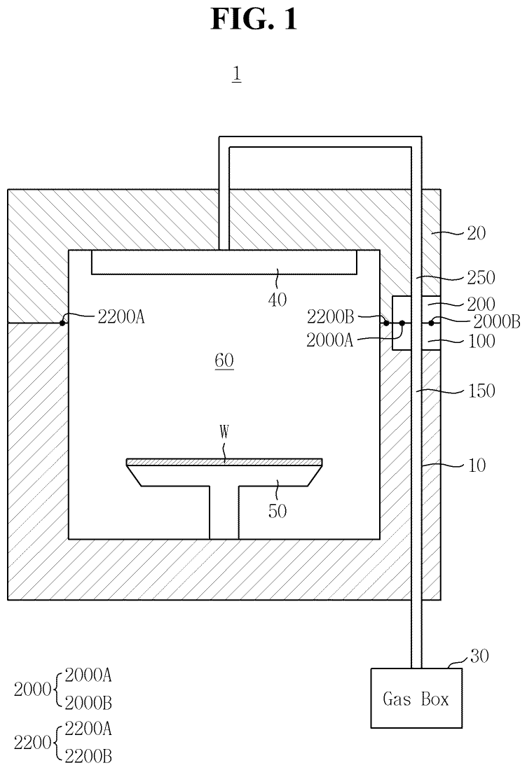

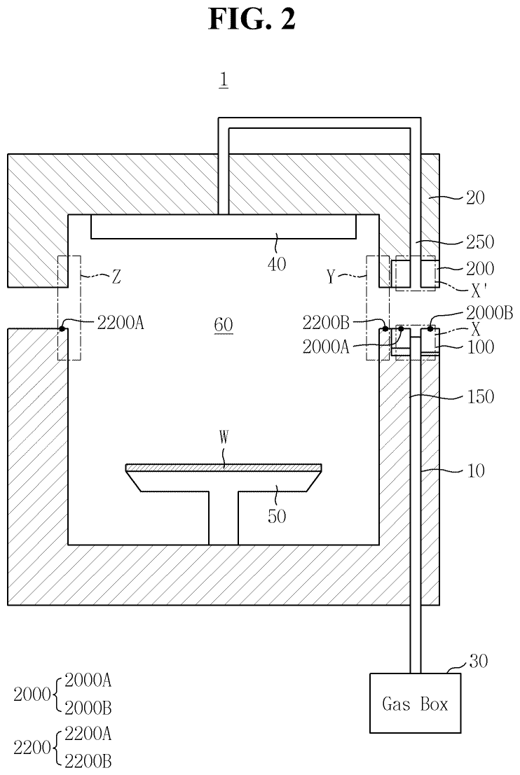

FIGS. 1 and 2 are schematic cross-sectional views illustrating an apparatus for treating a substrate according to some embodiments.

Referring to FIGS. 1 and 2, an apparatus 1 for treating a substrate may include an upper body 20 and a lower body 10.

The upper body 20 and the lower body 10 may be coupled to each other to form a chamber space 60. The chamber space 60 may enclose a shower head 40 and a support 50. For example, the shower head 40 may be attached on a ceiling of a chamber formed by the upper body 20 and the lower body 10, and the support 50 may be disposed at a bottom of the chamber. The support 50 may support a substrate W disposed on an upper surface thereof.

In some embodiments, the apparatus 1 may generate a thin film deposition material in the chamber space 60 by a precursor.

The apparatus 1 may include an upper gas supply line 250 and a lower gas supply line 150 in the upper body 20 and the lower body 10, respectively.

The upper gas supply line 250 may be connected to the upper body 20 by an upper connection portion 200. The lower gas supply line 150 may be connected to the lower body 10 by a lower connection portion 100. The upper gas supply line 250 may be connected to the lower gas supply line 150 as the upper connection portion 200 is in contact with the lower connection portion 100. The upper connection portion 200 and the lower connection portion 100 may be in contact with each other as the upper body 20 is in contact with the lower body 10. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

For example, when the upper body 20 and the lower body 10 come into contact with each other as shown in FIG. 1, the upper gas supply line 250 and the lower gas supply line 150 are connected with each other. For example, the upper gas supply line 250 may be gas supply path including a hole formed in the upper body 20 and in the upper connection portion 200, and the lower gas supply line 150 may be a gas supply path including a hole formed in the lower body 10 and in the lower connection portion 100.

However, as shown in FIG. 2, when the upper body 20 and the lower body 10 are not in contact with (separated from) each other, the upper gas supply line 250 and the lower gas supply line 150 are not connected to (separated from) each other.

A fluid supplied from a gas box 30 may be supplied to the shower head 40 in the chamber space 60 along/through the lower gas supply line 150 and the upper gas supply line 250. The shower head 40 may supply the fluid into the chamber space 60. For example, the fluid may be a precursor such as SiH₄ or N₂.

Although the upper gas supply line 250 and the lower gas supply line 150 are shown as passing through the upper body 20 and the lower body 10, the inventive concept is not limited thereto. The upper gas supply line 250 and the lower gas supply line 150 may be positioned outside the upper body 20 and the lower body 10.

The apparatus 1 may include a first sealing material 2000 and a second sealing material 2200.

The first sealing material 2000 may seal the upper gas supply line 250 and the lower gas supply line 150 from the outside. The second sealing material 2200 may seal the chamber space 60 from the outside. Each of sealing materials including the first sealing material 2000, the second sealing material 2200, and the other sealing materials described below in the present disclosure may be a sealing unit, e.g., a gasket or an O-ring, and may be formed of a material more elastic than a material forming the lower and upper bodies 10 and 20, and/or a material forming the lower and upper connection portions 100 and 200. A detailed description of the first sealing material 2000 and the second sealing material 2200 will be described later.

Although the first sealing material 2000 is shown as being positioned in the lower connection portion 100, the inventive concept is not limited thereto. Also, although the second sealing material 2200 is shown as being positioned in the lower body 10, the inventive concept is not limited thereto. For example, the first sealing material 2000 may be positioned in the upper connection portion 200. Also, the second sealing material 2200 may be certainly positioned in the upper body 20.

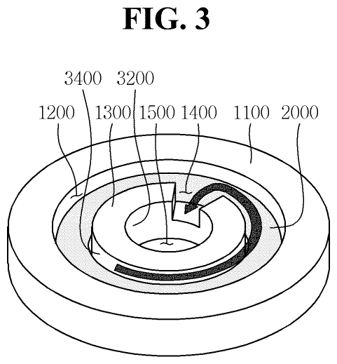

FIG. 3 is a perspective view illustrating a region X shown in FIG. 2.

Referring to FIG. 3, the lower connection portion 100 may include a first sealing groove 1200 on a surface that is in contact with and/or facing the upper connection portion 200. The lower connection portion 100 may include a first inner wall 1300 surrounding a lower flow path 1500 inside the first sealing groove 1200. The lower connection portion 100 may include a first outer wall 1100 outside the first sealing groove 1200.

The first sealing material 2000 may be inserted into the first sealing groove 1200.

The first inner wall 1300 may separate the lower flow path 1500 from the first sealing groove 1200.

The first sealing groove 1200 may be open to the outside when the upper connection portion 200 and the lower connection portion 100 are separated from each other. Also, the first sealing groove 1200 may be connected to the upper gas supply line 250 and the lower gas supply line 150 through a micro-gap formed between the first inner wall 1300 and the upper connection portion 200 such that fluid can flow between the first sealing groove 1200 and the upper gas supply line 250, and between the first sealing groove 1200 and the lower gas supply line 150 through the micro-gap.

The fluid flowing into the first sealing groove 1200 may not be smoothly discharged from a gap between the first sealing material 2000 and the first inner wall 1300. For example, the micro-gap formed between the first inner wall 1300 and the upper connection portion 200 may be too narrow to discharge fluid from the first sealing groove 1200.

According to some embodiments of the present disclosure, a first trench 1400 formed by removing a portion of the first inner wall 1300 may be provided on the first inner wall 1300. For example, the first inner wall 1300 may have a cylindrical shape with a certain height, and the first trench 1400 may be formed in certain portion of the first inner wall 1300. Therefore, the height of the first inner wall 1300 where the first trench 1400 is formed may be lower than the other parts of the first inner wall 1300. The first trench 1400 may fluidly connect the upper flow path 1550 and the lower flow path 1500 with/to the first sealing groove 1200. For example, the first trench 1400 may connect the upper flow path 1550 and the lower flow path 1500 to the first sealing groove 1200 such that a fluid (e.g., gases) may flow from the sealing groove 1200 to the lower and upper flow paths 1500 and 1550 and vice versa.

As the first trench 1400 is provided, a fluid flowing into an outer contact surface 3400 of the first inner wall 1300, on which the first sealing groove 1200 is in contact with the first inner wall 1300, may move along the outer contact surface 3400, and may be discharged through the first trench 1400.

Therefore, contamination due to the fluid that has not been discharged from the outer contact surface 3400 may be prevented from occurring.

Furthermore, as the fluid remaining on the outer contact surface 3400 is continuously accumulated, the fluid is supplied to the lower flow path 1500, whereby contamination may be prevented from occurring on the inner contact surface 3200 of the first inner wall 1300, on which the lower flow path 1500 is in contact with the first inner wall 1300.

Contaminants in the apparatus 1 may be smoothly discharged by the first trench 1400, so that the apparatus 1 with improved durability may be provided.

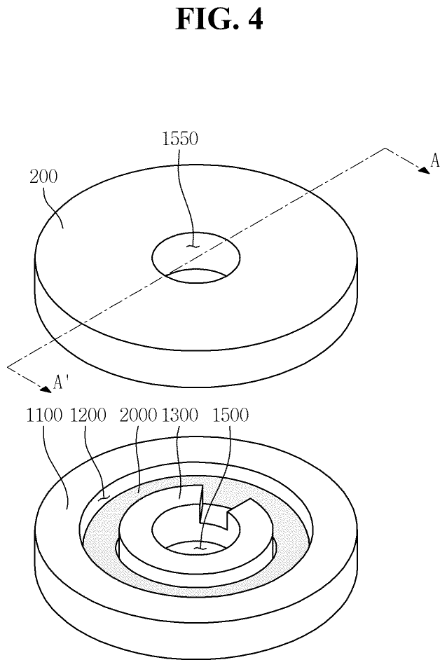

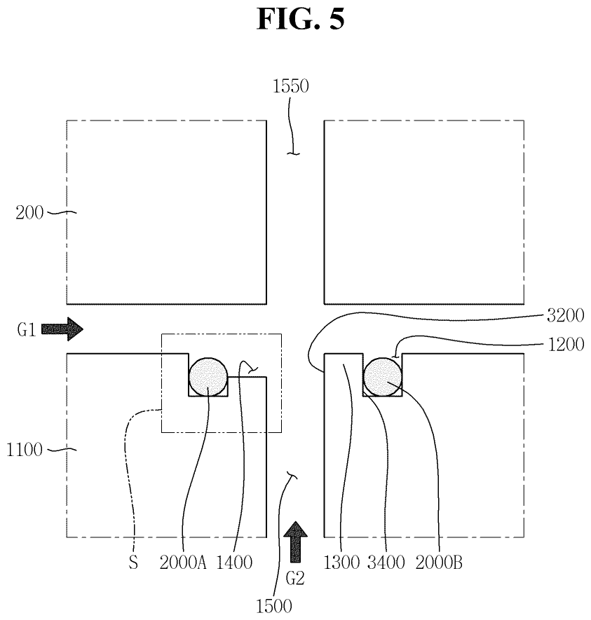

FIG. 4 is a perspective view illustrating a region X and a region X′, which are shown in FIG. 2. FIG. 5 is a cross-sectional view taken along line A-A′ of FIG. 4.

Referring to FIGS. 4 and 5, the lower connection portion 100 may include a first sealing groove 1200 on a surface that is in contact with and/or facing the upper connection portion 200. The lower connection portion 100 may include a first inner wall 1300 surrounding the lower flow path 1500 inside the first sealing groove 1200. The lower connection portion 100 may include a first outer wall 1100 outside the first sealing groove 1200.

The first sealing material 2000 may be inserted into the first sealing groove 1200. Although the first sealing groove 1200 is shown as being positioned in the lower connection portion 100, the inventive concept is not limited thereto. For example, the first sealing groove 1200 may be positioned in the upper connection portion 200.

When the upper connection portion 200 and the lower connection portion 100 are separated from each other, a first gas G1 flowing from the outside may flow into the first sealing groove 1200.

Also, when the upper connection portion 200 and the lower connection portion 100 are in contact with each other, a second gas G2 may be supplied through the upper flow path 1550 and the lower flow path 1500. In this case, the second gas G2 may flow into the first sealing groove 1200 through the micro-gap between the upper connection portion 200 and the first inner wall 1300.

In some embodiments, the second gas G2 may be a precursor for a deposition process. For example, the second gas G2 may be SiH₄ or N₂.

The first gas G1 or the second gas G2, which is flowing into the first sealing groove 1200, may not be smoothly discharged from the gap between the first sealing material 2000 and the first inner wall 1300.

In some embodiments, the first inner wall 1300 may include a first trench 1400 formed by removing a portion of the first inner wall 1300. As the first trench 1400 is provided on the first inner wall 1300, a fluid flowing into the outer contact surface 3400 of the first inner wall 1300, on which the first sealing groove 1200 is in contact with the first inner wall 1300, may move along the outer contact surface 3400, and may be discharged through the first trench 1400.

Therefore, the first trench 1400 may be helpful to discharge the fluid easily and smoothly, and contamination due to the fluid that has not been discharged from the outer contact surface 3400 or the inner contact surface 3200 may be prevented from occurring.

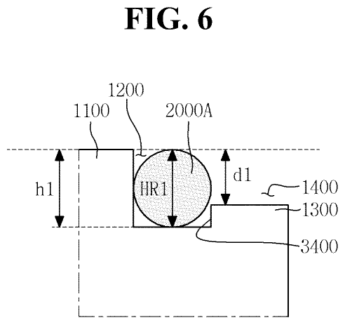

FIG. 6 is a cross-sectional view illustrating a region S shown in FIG. 5.

Referring to FIG. 6, the lower connection portion 100 may include a first outer wall 1100, a first sealing groove 1200 and a first inner wall 1300 on a surface that is in contact with and/or facing the upper connection portion 200.

A first sealing material 2000A may be inserted into the first sealing groove 1200.

In some embodiments, the first inner wall 1300 may include a first trench 1400 formed by removing a portion of the first inner wall 1300. For example, the first inner wall 1300 may have a cylindrical shape or a ring shape, and the first trench 1400 may be formed on an upper portion or a side of the first inner wall 1300, thereby the first inner wall 1300 may have a lower height at the portion where the first trench 1400 is placed than the other parts of the first inner wall 1300. As the first trench 1400 is provided on the first inner wall 1300, a fluid flowing into the outer contact surface 3400 of the first inner wall 1300, on which the first sealing groove 1200 is in contact with the first inner wall 1300, may move along the outer contact surface 3400, and may be discharged through the first trench 1400.

In some embodiments, the first sealing material 2000A may have a first sealing material height HR1. In addition, a height of the first outer wall 1100, which is measured from a bottom surface of the first sealing groove 1200 to an upper surface of the first outer wall 1100, may be a first height h1.

A depth of the first trench 1400, which is measured vertically from the same plane/level as the upper surface of the first outer wall 1100 to the upper surface of the first inner wall 1300 at the first trench 1400, may be a first depth d1.

In some embodiments, the first depth d1 may be smaller than the first height h1. For example, the upper surface of the first inner wall 1300, which forms a bottom surface of the first trench 1400, may be positioned to be higher than the bottom surface of the first sealing groove 1200.

In some embodiments, the first depth d1 of the first trench 1400 may be greater than half of the height HR1 of the first sealing material 2000A. Therefore, the fluid flowing into the outer contact surface 3400 of the first inner wall 1300 may be smoothly discharged through the first trench 1400.

As the contaminants in the apparatus 1 are smoothly discharged, the apparatus 1 with improved durability may be provided.

Although the first height h1 of the first outer wall 1100 is shown as being the same as the first sealing material height HR1, the inventive concept is not limited thereto. For example, the first sealing material height HR1 may be greater than the first height h1.

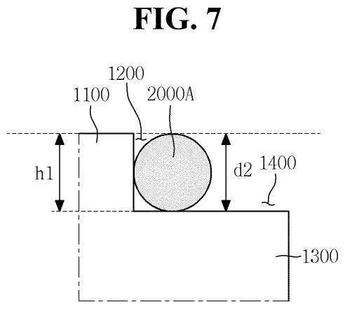

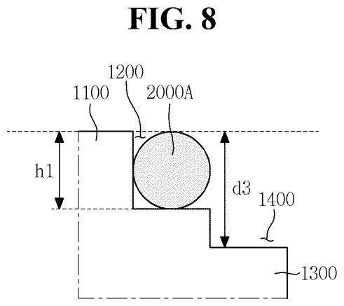

FIGS. 7 and 8 are cross-sectional views illustrating some elements of an apparatus for treating a substrate according to some embodiments. Since FIGS. 7 and 8 are views corresponding to FIG. 6, the following description will be based on differences from FIG. 6 for convenience of description. For example, elements not described with respect to FIGS. 7 and 8 may be the same as the ones described with respect to FIG. 6.

Referring to FIG. 7, a height of the first outer wall 1100, which is measured from the bottom surface of the first sealing groove 1200 to the upper surface of the first outer wall 1100, may be the first height h1.

The depth of the first trench 1400, which is measured vertically from the same plane/level as the upper surface of the first outer wall 1100 to the upper surface of the first inner wall 1300 at the first trench 1400, may be a second depth d2.

In some embodiments, the second depth d2 of the first trench 1400 may be the same as the first height h1. For example, the upper surface of the first inner wall 1300, which forms a bottom surface of the first trench 1400, may be positioned on the same plane or at the same level as the bottom surface of the first sealing groove 1200.

Therefore, the fluid flowing into the outer contact surface 3400 of the first inner wall 1300 may be smoothly discharged through the first trench 1400.

As the contaminants in the apparatus 1 are smoothly discharged, the apparatus 1 with improved durability may be provided.

Referring to FIG. 8, the height of the first outer wall 1100, which is measured from the bottom surface of the first sealing groove 1200 to the upper surface of the first outer wall 1100, may be the first height h1.

The depth of the first trench 1400, which is measured vertically from the same plane/level as the upper surface of the first outer wall 1100 to the upper surface of the first inner wall 1300 at the first trench 1400, may be a third depth d3.

In some embodiments, the third depth d3 of the first trench 1400 may be greater than the first height h1. For example, the upper surface of the first inner wall 1300, which forms a bottom surface of the first trench 1400, may be positioned to be lower than the bottom surface of the first sealing groove 1200.

Therefore, the fluid flowing into the outer contact surface 3400 of the first inner wall 1300 may be smoothly discharged through the first trench 1400. As the contaminants in the apparatus 1 are smoothly discharged, the apparatus 1 with improved durability may be provided.

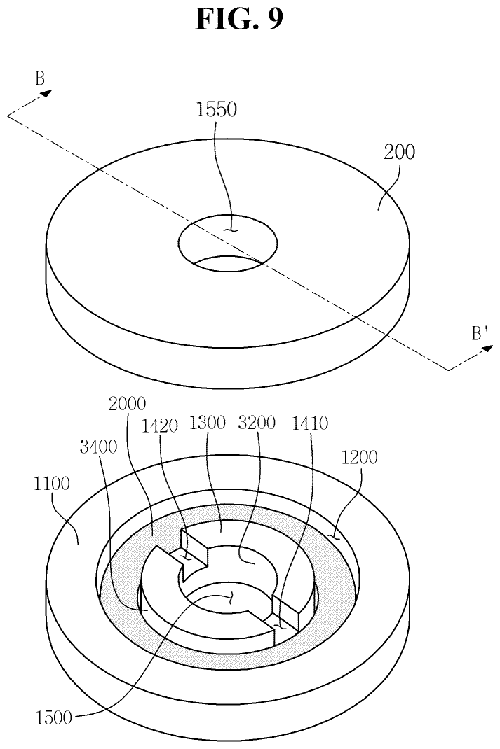

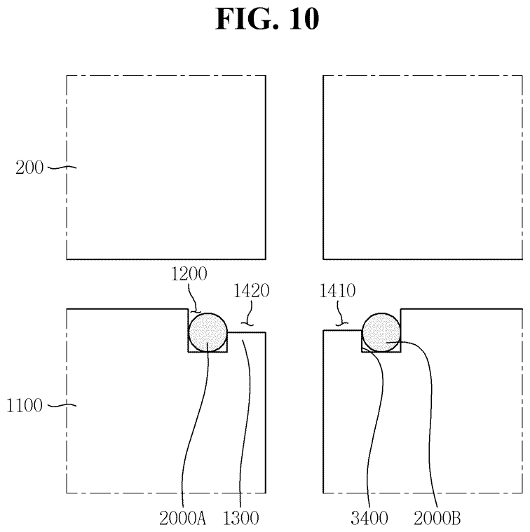

FIG. 9 is a perspective view illustrating some elements of an apparatus for treating a substrate according to some embodiments. FIG. 10 is a cross-sectional view taken along line B-B′ of FIG. 9.

Referring to FIGS. 9 and 10, the lower connection portion 100 may include a first sealing groove 1200 on a surface that is in contact with and/or facing the upper connection portion 200. The lower connection portion 100 may include a first inner wall 1300 surrounding the lower flow path 1500 inside the first sealing groove 1200. The lower connection portion 100 may include a first outer wall 1100 outside the first sealing groove 1200.

The first sealing material 2000 may be inserted into the first sealing groove 1200.

The first inner wall 1300 may separate the lower flow path 1500 from the first sealing groove 1200.

In some embodiments, the first inner wall 1300 may include a plurality of first trenches 1410 and 1420 formed by removing a portion of the first inner wall 1300. The first trenches 1410 and 1420 may fluidly connect the lower flow path 1500 with/to the first sealing groove 1200. For example, the first trenches 1410 and 1420 may connect the lower flow path 1500 to the first sealing groove 1200 such that fluid (e.g., gases) may flow between the first sealing groove 1200 and the lower flow path 1500 through the first trenches 1410 and 1420.

The plurality of first trenches 1410 and 1420 may be separated from each other by the first inner wall 1300. For example, the first trenches 1410 and 1420 may be formed in the first inner wall 1300 and may be spaced apart from each other such that portions of the inner wall 1300 are interposed between the first trenches 1410 and 1420.

In some embodiments, an angle between the first trench 1410 and the first trench 1420 may be 180 degrees. For example, an angle formed by a line connecting a center point of the inner wall 1300 and a center point of the first trench 1410 in a plan view and a line connecting the center point of the inner wall 1300 and a center point of the first trench 1420 in the plan view may be 180 degrees, but the inventive concept is not limited thereto.

As the number of the first trenches 1410 and 1420 is increased, the fluid flowing into the outer contact surface 3400 of the first inner wall 1300 may be smoothly discharged through the first trenches 1410 and 1420.

Therefore, contamination due to the fluid that has not been discharged from the outer contact surface 3400 or the inner contact surface 3200 may be prevented from occurring. As the contaminants in the apparatus 1 are smoothly discharged, the apparatus 1 with improved durability may be provided.

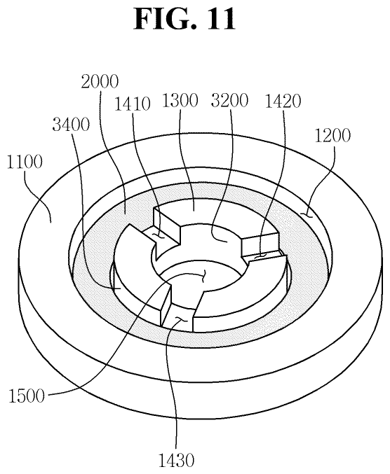

FIGS. 11 to 13 are perspective views illustrating some elements of an apparatus for treating a substrate according to some embodiments.

Referring to FIG. 11, the lower connection portion 100 may include a first sealing groove 1200 on a surface that is in contact with and/or facing the upper connection portion 200. The lower connection portion 100 may include a first inner wall 1300 surrounding the lower flow path 1500 inside the first sealing groove 1200. The lower connection portion 100 may include a first outer wall 1100 outside the first sealing groove 1200.

The first sealing material 2000 may be inserted into the first sealing groove 1200.

The first inner wall 1300 may separate the lower flow path 1500 from the first sealing groove 1200. The first inner wall 1300 may include a plurality of first trenches 1410, 1420 and 1430 formed by removing a portion of the first inner wall 1300 (e.g., formed in the first inner wall 1300). The plurality of first trenches 1410, 1420 and 1430 may fluidly connect the lower flow path 1500 with/to the first sealing groove 1200. For example, the plurality of first trenches 1410, 1420, and 1430 may connect the first sealing groove 1200 to the lower flow path 1500 such that a fluid may flow from the first sealing groove 1200 to the lower flow path 1500 and/or from the lower flow path 1500 to the first sealing groove 1200.

The plurality of first trenches 1410, 1420 and 1430 may be separated from one another by the first inner wall 1300. For example, the plurality of first trenches 1410, 1420, and 1430 may be formed in the first inner wall 1300 such that portions of the first inner wall 1300 are interposed between the first trenches 1410, 1420, and 1430. For example, the first trenches 1410, 1420, and 1430 may be spaced apart from each other in the first inner wall 1300.

In some embodiments, an angle among the plurality of first trenches 1410, 1420 and 1430 may be 120 degrees. For example, an angle between a first line connecting a center of the first inner wall 1300 and a center of the first trench 1410 and a second line connecting the center of the first inner wall 1300 and a center of the first trench 1420 in a plan view may be 120 degrees, an angle between the second line and a third line connecting the center of the first inner wall 1300 and a center of the first trench 1430 in the plan view may be 120 degrees, and an angle between the first line and the third line may be 120 degrees, but the inventive concept is not limited thereto.

As the number of the first trenches 1410, 1420 and 1430 is increased, the fluid flowing into the outer contact surface 3400 of the first inner wall 1300 may be smoothly discharged through the first trenches 1410, 1420 and 1430.

As the contaminants in the apparatus 1 are smoothly discharged, the apparatus 1 with improved durability may be provided.

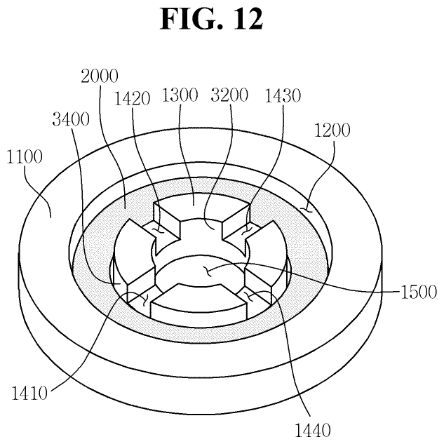

Referring to FIG. 12, the lower connection portion 100 may include a first sealing groove 1200 on a surface that is in contact with and/or facing the upper connection portion 200. The lower connection portion 100 may include a first inner wall 1300 surrounding the lower flow path 1500 inside the first sealing groove 1200. The lower connection portion 100 may include a first outer wall 1100 outside the first sealing groove 1200.

The first sealing material 2000 may be inserted into the first sealing groove 1200.

The first inner wall 1300 may separate the lower flow path 1500 from the first sealing groove 1200. The first inner wall 1300 may include a plurality of first trenches 1410, 1420, 1430 and 1440 formed by removing a portion of the first inner wall 1300 (e.g., formed in the first inner wall 1300). The plurality of first trenches 1410, 1420, 1430 and 1440 may fluidly connect the lower flow path 1500 with the first sealing groove 1200. For example, the plurality of first trenches 1410, 1420, 1430, and 1440 may connect the first sealing groove 1200 to the lower flow path 1500 such that a fluid (e.g., gases) may flow from the first sealing groove 1200 to the lower flow path 1500 through the plurality of first trenches 1410, 1420, 1430, and 1440, and/or flow from the lower flow path 1500 to the first sealing groove 1200 through the plurality of first trenches 1410, 1420, 1430, and 1440.

The plurality of first trenches 1410, 1420, 1430 and 1440 may be separated from one another by the first inner wall 1300. For example, the plurality of first trenches 1410, 1420, 1430 and 1440 may be formed in the first inner wall 1300 such that portions of the first inner wall 1300 are interposed between the first trenches 1410, 1420, 1430 and 1440. For example, the first trenches 1410, 1420, 1430 and 1440 may be spaced apart from each other in the first inner wall 1300.

In some embodiments, an angle among the plurality of first trenches 1410, 1420, 1430 and 1440 may be 90 degrees. For example, an angle between a first line connecting a center of the first inner wall 1300 and a center of the first trench 1410 and a second line connecting the center of the first inner wall 1300 and a center of the first trench 1420 in a plan view may be 90 degrees, an angle between the second line and a third line connecting the center of the first inner wall 1300 and a center of the first trench 1430 in the plan view may be 90 degrees, an angle between the third line and a fourth line connecting the center of the first inner wall 1300 and a center of the first trench 1440 in the plan view may be 90 degrees, and an angle between the first line and the fourth line may be 90 degrees, but the inventive concept is not limited thereto.

As the number of the first trenches 1410, 1420, 1430 and 1440 is increased, the fluid flowing into the outer contact surface 3400 of the first inner wall 1300 may be smoothly discharged through the first trenches 1410, 1420, 1430 and 1440.

As the contaminants in the apparatus 1 are smoothly discharged, the apparatus 1 with improved durability may be provided.

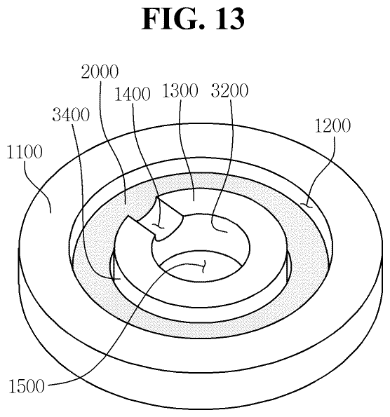

Referring to FIG. 13, the lower connection portion 100 may include a first sealing groove 1200 on a surface that is in contact with and/or facing the upper connection portion 200. The lower connection portion 100 may include a first inner wall 1300 surrounding the lower flow path 1500 inside the first sealing groove 1200. The lower connection portion 100 may include a first outer wall 1100 outside the first sealing groove 1200.

The first sealing material 2000 may be inserted into the first sealing groove 1200.

The first inner wall 1300 may separate the lower flow path 1500 from the first sealing groove 1200. The first inner wall 1300 may include a first trench 1400 formed by removing a portion of the first inner wall 1300 (e.g., formed in the first inner wall 1300). The first trench 1400 may fluidly connect the lower flow path 1500 with/to the first sealing groove 1200. For example, the first trench 1400 may connect toe first sealing groove 1200 to the lower flow path 1500 such that a fluid (e.g., a gas) may flow from the first sealing groove 1200 to the lower flow path 1500 and/or may flow from the lower flow path 1500 to the first sealing groove 1200.

Therefore, the fluid flowing into the outer contact surface 3400 of the first inner wall 1300 may be smoothly discharged through the first trench 1400. As the contaminants in the apparatus 1 are smoothly discharged, the apparatus 1 with improved durability may be provided.

In some embodiments, the upper surface of the first inner wall 1300, which is in contact with or forms a bottom surface of the first trench 1400, may have a concave shape. Therefore, contaminants accumulated on the upper surface of the first inner wall 1300, which is in contact with or forms the bottom surface of the first trench 1400, may be easily removed.

As a result, the apparatus 1 with improved durability may be provided.

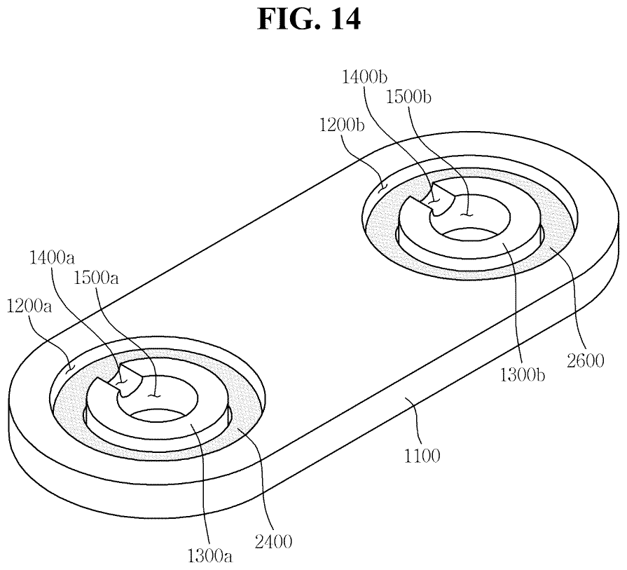

FIG. 14 is a perspective view illustrating some elements of an apparatus for treating a substrate according to some embodiments.

Referring to FIG. 14, the lower gas supply line 150 may include a first sub-flow path 1500a and a second sub-flow path 1500b, which extend in parallel with each other.

The lower connection portion 100 may include a first sub-sealing groove 1200a on a surface where the lower connection portion 100 is in contact with or faces the upper connection portion 200. The lower connection portion 100 may include a first sub-sealing inner wall 1300a surrounding the first sub-flow path 1500a inside the first sub-sealing groove 1200a. The lower connection portion 100 may include a first outer wall 1100 outside the first sub-sealing groove 1200a.

A first sub-sealing material 2400 may be inserted into the first sub-sealing groove 1200a.

The first sub-inner wall 1300a may separate the first sub-flow path 1500a from the first sub-sealing groove 1200a. The first sub-inner wall 1300a may include a first sub-trench 1400a formed by removing a portion of or formed in the first sub-inner wall 1300a. The first sub-trench 1400a may fluidly connect the first sub-flow path 1500a with/to the first sub-sealing groove 1200a. For example, the first sub-trench 1400a may connect the first sub-sealing groove 1200a to the first sub-flow path 1500a such that a fluid (e.g., a gas) may flow from the first sub-sealing groove 1200a to the first sub-flow path 1500a. For example, the fluid may be supplied into the chamber space 60 along the first sub-flow path 1500a. For example, the fluid may be a precursor such as SiH₄ or N₂.

The lower connection portion 100 may include a second sub-sealing groove 1200b on a surface where the lower connection portion 100 is in contact with or faces the upper connection portion 200. The lower connection portion 100 may include a second sub-sealing inner wall 1300b surrounding the second sub-flow path 1500b inside the second sub-sealing groove 1200b. The lower connection portion 100 may include a first outer wall 1100 outside the second sub-sealing groove 1200b.

A second sub-sealing material 2600 may be inserted into the second sub-sealing groove 1200b.

The second sub-inner wall 1300b may separate the second sub-flow path 1500b from the second sub-sealing groove 1200b. The second sub-inner wall 1300b may include a second sub-trench 1400b formed by removing a portion of or formed in the second sub-inner wall 1300b. The second sub-trench 1400b may fluidly connect the second sub-flow path 1500b with/to the second sub-sealing groove 1200b. For example, the second sub-trench 1400b may connect the second sub-sealing groove 1200b to the second sub-flow path 1500b such that a fluid (e.g., a gas) may flow from the second sub-sealing groove 1200b to the second sub-flow path 1500b. For example, the fluid may be supplied into the chamber space 60 along/through the second sub-flow path 1500b. For example, the fluid may be N₂ or Ar.

The first sub-sealing groove 1200a and the second sub-sealing groove 1200b may be separated from each other by the first outer wall 1100.

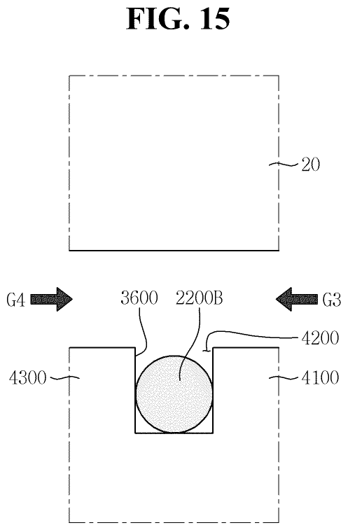

FIG. 15 is a cross-sectional view illustrating a region Y shown in FIG. 2.

Referring to FIG. 15, the lower body 10 may include a second sealing groove 4200 on a surface that is in contact with and/or facing the upper body 20. The lower body 10 may include a second inner wall 4300 surrounding the chamber space 60 inside the second sealing groove 4200 (e.g., closer to the chamber space 60 than the second sealing groove 4200). The lower body 10 may include a second outer wall 4100 outside the second sealing groove 4200.

The second sealing material 2200 may be inserted into the second sealing groove 4200. Although the second sealing groove 4200 is shown as being positioned in the lower body 10, the inventive concept is not limited thereto. For example, the second sealing groove 4200 may be positioned in the upper body 20 in certain embodiments.

When the upper body 20 and the lower body 10 are separated from each other, a third gas G3 flowing from the outside may flow into the second sealing groove 4200.

Furthermore, even though the upper body 20 and the lower body 10 come into contact with each other, a fourth gas G4 in the chamber space 60 may flow into the second sealing groove 4200 through a micro-gap between the upper body 20 and the second inner wall 4300.

The third gas G3 or the fourth gas G4, which flows into the second sealing groove 4200, may not be smoothly discharged from a gap between the second sealing material 2200 and the second inner wall 4300.

Therefore, contaminants may be accumulated on an outer contact surface 3600 of the second inner wall 4300, on which the second sealing groove 4200 and the second inner wall 4300 are in contact with each other.

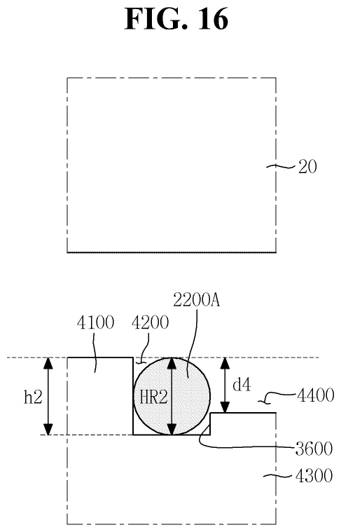

FIGS. 16 to 18 are cross-sectional views illustrating a region Z shown in FIG. 2.

Referring to FIGS. 15 and 16, the lower body 10 may include a second sealing groove 4200 on a surface that is in contact with and/or facing the upper body 20. The lower body 10 may include a second inner wall 4300 surrounding the chamber space 60 inside the second sealing groove 4200. The lower body 10 may include a second outer wall 4100 outside the second sealing groove 4200.

The second sealing material 2200 may be inserted into the second sealing groove 4200.

In some embodiments, the second inner wall 4300 may include a second trench 4400 formed by removing a portion of or formed in the second inner wall 4300. As the second trench 4400 is provided on the second inner wall 4300, the fluid flowing into the outer contact surface 3600 of the second inner wall 4300, on which the second sealing groove 4200 is in contact with the second inner wall 4300, may move along the outer contact surface 3600, and may be discharged through the second trench 4400.

In some embodiments, the second sealing material 2200 may have a second sealing material height HR2. In addition, a height of the second outer wall 4100, which is measured from a bottom surface of the second sealing groove 4200 to an upper surface of the second outer wall 4100, may be a second height h2.

A depth of the second trench 4400, which is measured vertically from the same plane/level as the upper surface of the second outer wall 4100 to an upper surface of the second inner wall 4300 at the second trench 4400, may be a fourth depth d4.

In some embodiments, the fourth depth d4 may be smaller than the second height h2. For example, the upper surface of the second inner wall 4300, which forms a bottom surface of the second trench 4400, may be positioned to be higher than the bottom surface of the second sealing groove 4200.

In some embodiments, the fourth depth d4 of the second trench 4400 may be greater than half of the second sealing material height HR2 of the second sealing material 2200. Therefore, the fluid flowing into the outer contact surface 3600 of the second inner wall 4300 may be smoothly discharged through the second trench 4400.

As the contaminants in the apparatus 1 are smoothly discharged, the apparatus 1 with improved durability may be provided.

Although the second height h2 of the second outer wall 4100 is shown as being the same as the second sealing material height HR2, the inventive concept is not limited thereto. For example, the second sealing material height HR2 may be greater than the second height h2 in certain embodiments.

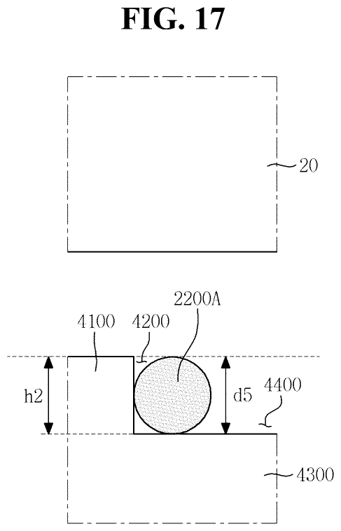

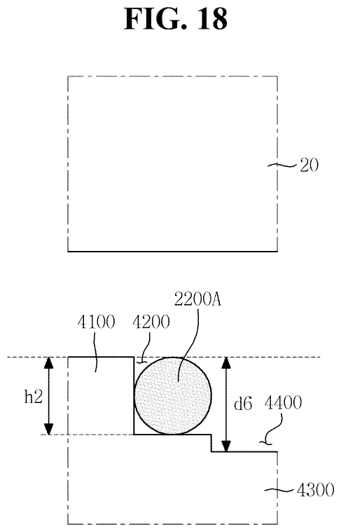

FIGS. 17 and 18 are cross-sectional views illustrating some elements of an apparatus for treating a substrate according to some embodiments. Since FIGS. 17 and 18 are views corresponding to FIG. 16, the following description will be based on differences from FIG. 16 for convenience of description. For example, elements not described with respect to FIGS. 17 and 18 may be the same as the ones described with respect to FIG. 16.

Referring to FIG. 17, a height of the second outer wall 4100, which is measured from the bottom surface of the second sealing groove 4200 to the upper surface of the second outer wall 4100, may be the second height h2.

The depth of the second trench 4400, which is measured vertically from the same plane/level as the upper surface of the second outer wall 4100 to the upper surface of the second inner wall 4300, may be a fifth depth d5.

In some embodiments, the fifth depth d5 of the second trench 4400 may be the same as the second height h2. For example, the upper surface of the second inner wall 4300, which forms a bottom surface of the second trench 4400, may be positioned on the same plane or at the same level as the bottom surface of the second sealing groove 4200.

Therefore, the fluid flowing into the outer contact surface 3600 of the second inner wall 4300 may be smoothly discharged through the second trench 4400. As the contaminants in the apparatus 1 are smoothly discharged, the apparatus 1 with improved durability may be provided.

Referring to FIG. 18, the height of the second outer wall 4100, which is measured from the bottom surface of the second sealing groove 4200 to the upper surface of the second outer wall 4100, may be the second height h2.

The depth of the second trench 4400, which is measured vertically from the same plane/level as the upper surface of the second outer wall 4100 to the upper surface of the second inner wall 4300 at the second trench 4400, may be a sixth depth d6.

In some embodiments, the sixth depth d6 of the second trench 4400 may be greater than the second height h2. For example, the upper surface of the second inner wall 4300, which forms a bottom surface of the second trench 4400, may be positioned to be lower than the bottom surface of the second sealing groove 4200.

Therefore, the fluid flowing into the outer contact surface 3600 of the second inner wall 4300 may be smoothly discharged through the second trench 4400. As the contaminants in the apparatus 1 are smoothly discharged, the apparatus 1 with improved durability may be provided.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

Although the embodiments of the present disclosure have been described with reference to the accompanying drawings, it will be apparent to those skilled in the art that the present disclosure may be fabricated in various forms without being limited to the above-described embodiments and may be embodied in other specific forms without departing from technical spirits and essential characteristics of the present disclosure. Thus, the above embodiments are to be considered in all respects as illustrative and not restrictive.

What is claimed is:

1. An apparatus for treating a substrate, the apparatus comprising:
a first body;
a second body forming a chamber space therein in contact with the first body;
a first connection portion disposed between the first body and the second body:
a second connection portion disposed between the first body and the second body;
a first gas supply line installed in the first body and the first connection portion; and
a second gas supply line installed in the second body and the second connection portion, the second connection portion configured to contact the first connection portion,
wherein the first connection portion includes
a sealing groove, into which a gasket is inserted, on a surface that is in contact with the second connection portion,
an inner wall separating a first flow path of the first gas supply line from the sealing groove, and
a trench installed on the inner wall and fluidly connecting the first flow path to the sealing groove.

2. The apparatus of claim 1, wherein a height of the inner wall is greater than a depth of the trench.

3. The apparatus of claim 2, wherein the depth of the trench is greater than half of a height of the gasket.

4. The apparatus of claim 1, wherein a height of the inner wall is the same as a depth of the trench.

5. The apparatus of claim 1, wherein a height of the inner wall is smaller than a depth of the trench.

6. The apparatus of claim 1, wherein a bottom surface of the trench is concave.

7. The apparatus of claim 1, wherein the first gas supply line includes a first sub-line and a second sub-line, which extend in parallel with each other,
the first connection portion further includes a another sealing groove into which another gasket is inserted, another inner wall separating the another sealing groove from a second flow path, and another trench installed on the another inner wall to fluidly connect the second flow path to the another sealing groove, and
the first sub-line and the second sub-line are separated from each other by an outer wall interposed therebetween.

8. The apparatus of claim 1, wherein two or more trenches are formed on the inner wall.

9. The apparatus of claim 8, wherein the trenches include a first trench and a second trench, and
the first trench and the second trench are separated from each other by a portion of the inner wall interposed therebetween.

10. The apparatus of claim 9, wherein the inner wall has a circular shape in a plan view, and the first trench and the second trench are disposed opposite each other on the circular shape.

11. The apparatus of claim 1, wherein the first and second gas supply lines are configured such that SiH₄ or N₂ is supplied along the first gas supply line and the second gas supply line.

12. An apparatus for treating a substrate, the apparatus comprising:
a first body;
a second body forming a chamber space therein in contact with the first body; and
a gasket surrounding the chamber space and sealing the chamber space from an outside,
wherein the first body includes
a sealing groove, into which the gasket is inserted, on a surface that is in contact with the second body,
an inner wall separating the sealing groove from the chamber space, and
a trench installed on the inner wall and fluidly connecting the chamber space to the sealing groove.

13. The apparatus of claim 12, wherein a height of the inner wall is greater than or equal to a depth of the trench.

14. The apparatus of claim 13, wherein the depth of the trench is greater than half of a height of the gasket.

15. The apparatus of claim 12, wherein a height of the inner wall is smaller than a depth of the trench.

16. The apparatus of claim 12, wherein a bottom surface of the trench is concave.

17. The apparatus of claim 12, wherein two or more trenches are formed in the inner wall.

18. The apparatus of claim 17, wherein the trenches include a first trench and a second trench, and
the first trench and the second trench are separated from each other by a portion of the inner wall interposed therebetween.

19. The apparatus of claim 18, wherein the inner wall has a circular shape in a plan view, and the first trench and the second trench are disposed opposite each other on the circular shape.

20. An apparatus for treating a substrate, the apparatus comprising:
a first body;
a second body forming a chamber space therein in contact with the first body;
a first gas supply line installed in the first body and in a first connection portion; and
a second gas supply line installed in the second body and in a second connection portion configured to contact the first connection portion,
wherein the first connection portion includes
a sealing groove, into which a gasket is inserted, on a surface that is in contact with the second connection portion,
an inner wall separating a first flow path of the first gas supply line from the sealing groove, and
one or more trenches installed on the inner wall and fluidly connecting the first flow path to the sealing groove,
a height of the inner wall is greater than a depth of the trench, and
the depth of the trench is greater than half of a height of the gasket.
